(19) United States
(12) Patent Application Publication
(10) Pub. No.: US 2024/0194805 A1
(43) Pub. Date: Jun. 13, 2024

(54) PHOTODIODE STRUCTURE

(71) Applicant: Taiwan-Asia Semiconductor Corporation, Hsinchu City (TW)

(72) Inventors: Yen-Hsiang CHANG, Taichung (TW); Sheng-Wei CHEN, Hsinchu City (TW)

(21) Appl. No.: 18/529,861

(22) Filed: Dec. 5, 2023

(30) Foreign Application Priority Data
Dec. 8, 2022 (TW) 111147283

(51) Int. Cl. H01L 31/0232; H01L 31/0216

(52) U.S. Cl. CPC H01L 31/02327; H01L 31/02162

(57) ABSTRACT

The present invention provides a photodiode structure, which includes a chip, an electrode group, an electrode protection layer and a metal alloy band-pass optical film. The electrode group is arranged on the chip, and the electrode group includes a positive electrode and a negative electrode; the electrode protection layer is arranged on the chip and covers the electrode group; the metal alloy band-pass optical film is arranged on the electrode protection layer and includes a plurality of layered structures, and the plurality of layered structures includes at least two metal alloy material layers.

### CROSS-REFERENCES TO RELATED APPLICATIONS

This application claims the benefit of priority to Taiwanese Patent Application No. 111147283 filed on Dec. 8, 2022, which is hereby incorporated by reference in its entirety.

### BACKGROUND OF THE INVENTION

### Field of the Invention

The present invention relates to a photodiode structure, in particular to a photodiode using metal alloy band-pass optical films.

### Descriptions of the Related Art

Photodiodes are utilized to receive external light and generate corresponding analog electrical signals or to switch between various modes in electronic circuits. Currently, photodiodes are widely used in products that require optical measurement. For example, many smart wearable devices employ photodiodes to perform functions such as pulse rate measurement and/or blood oxygen measurement.

It is known that during the manufacturing process of photodiodes, the required N-type and P-type semiconductor layers are first formed as the main body of the chip, and then two electrodes, an oxide protection layer and a band-pass optical film are sequentially formed on the top surface of these semiconductor layers. At present, a single metal (such as silver) band-pass optical film or a dielectric band-pass optical film is used as the band-pass optical film. As for the single metal band-pass optical film, the single metal band-pass optical film is in direct contact with the electrode and easily cause an electrical short circuit. Moreover, the single metal band-pass optical film itself has low tolerance to environmental testing, making it susceptible to metal oxidation and migration phenomenon, which can negatively impact the sensing performance of the photodiode. In addition, in the case of the dielectric band-pass optical film, achieving an ideal filtering effect often requires stacking dozens of layered structures. This, in turn, leads to an increase in the thickness of the optical film and a more complex manufacturing process, resulting in the increase of manufacturing costs.

Therefore, designing a photodiode structure that can address the aforementioned problems is indeed a research topic worth investigating.

### SUMMARY OF THE INVENTION

One of the objectives of the present invention is to provide a photodiode using a metal alloy band-pass optical film.

To achieve the above objective, the present invention provides a photodiode structure which includes a chip, an electrode group, an electrode protection layer and a metal alloy band-pass optical film. The electrode group is arranged on the chip and includes a positive electrode and a negative electrode. The electrode protection layer is arranged on the chip and covers the electrode group. The metal alloy band-pass optical film is arranged on the electrode protection layer and includes a plurality of layered structures wherein the plurality of layered structures includes at least two metal alloy material layers.

In one embodiment of the present invention, the electrode protection layer is made of an optical transparent glue or an optical transparent photoresist.

In one embodiment of the present invention, the optical transparent glue comprises siloxanes, polysiloxanes, acrylics or epoxy resins.

In one embodiment of the present invention, the optical transparent photoresist comprises siloxanes or acrylics.

In one embodiment of the present invention, the electrode protection layer has a refractive index ranging between 1.45 and 1.6.

In one embodiment of the present invention, the electrode protection layer has a thickness measured from a top surface of the chip and greater than a height of the electrode group.

In one embodiment of the present invention, each of the metal alloy material layers is made of a silver platinum alloy material.

In one embodiment of the present invention, a ratio of silver to platinum in the silver-platinum alloy material is 95:5.

In one embodiment of the present invention, the plurality of layered structures further includes at least one of a silicon dioxide layer, a titanium dioxide layer, a tantalum pentoxide layer and a niobium pentoxide layer.

In one embodiment of the present invention, for a light in a wavelength range between 400 nm to 600 nm, the metal alloy band-pass optical film has a light transmittance of 80% or more.

In one embodiment of the present invention, for a light in a wavelength range between 300 nm to 399 nm, the metal alloy band-pass optical film has a light transmittance of 1% or less.

In one embodiment of the present invention, the photodiode structure further includes a plurality of electric wires, and each of the electric wires penetrates the metal alloy band-pass optical film and the electrode protection layer and is connected to the electrode group.

Accordingly, the photodiode structure of the present invention primarily uses a metal alloy band-pass optical film to improve its tolerance to environment and reduce the occurrence of metal oxidation migration phenomenon. Compared with the conventional photodiode using a single metal band-pass optical film, the number of layers and thickness of the metal alloy band-pass optical film of the photodiode structure in the present invention can be effectively reduced. Thereby, production capacity will be enhanced and the manufacturing costs will be reduced. Additionally, the photodiode structure of the present invention can effectively protect the electrodes and the chip to avoid electrical short circuits through the arrangement of optical-grade electrode protection layer.

### BRIEF DESCRIPTION OF THE DRAWINGS

FIG. 1 is a schematic view of the photodiode structure according to the present invention.

FIG. 2 is a schematic view of a metal alloy band-pass optical film of an embodiment of the photodiode structure according to the present invention.

FIG. 3 is a comparison diagram of the test result of the photodiode structure of the embodiment according to the present invention and the conventional photodiode structure.

### DETAILED DESCRIPTION OF THE PREFERRED EMBODIMENT

Since various aspects and embodiments are merely illustrative and non-restrictive, those skilled in the art may conceive other aspects and embodiments without departing from the scope of the present invention. The features and advantages of these embodiments will become apparent from the following detailed description and the appended claims.

Herein, the term “one”, “a” or “an” is used to describe the elements and components described herein. This is done for convenience of explanation only and to provide a general sense of the scope of the invention. Accordingly, unless otherwise indicated, the term “one”, “a” or “an” should be understood to encompass one or at least one, and the singular form also includes the plural form.

Herein, the terms “first”, “second” and other similar ordinal numbers are mainly used to distinguish or refer to the same or similar elements or structures, and do not necessarily imply the spatial or temporal order of such devices or structures. It should be understood that in certain situations or configurations, ordinal numbers may be used interchangeably without affecting the implementation of the invention.

As used herein, the terms “comprise”, “includes,” “have,” or any other similar term is intended to cover non-exclusive inclusions. For example, an element or structure containing plural elements is not limited to the elements listed herein, but may include other elements not expressly listed but that are generally inherent to the element or structure.

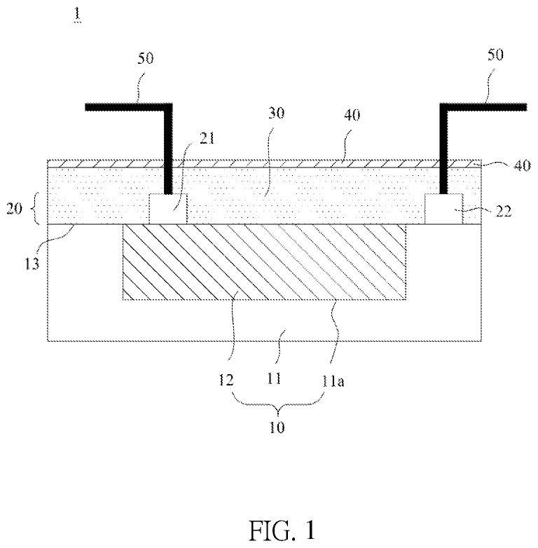

Reference is made to FIG. 1 which is a schematic view of the photodiode structure according to the present invention. As shown in FIG. 1, the photodiode structure 1 according to the present invention includes a chip 10, an electrode group 20, an electrode protection layer 30 and a metal alloy band-pass optical film 40. The chip 10 serving as a basic component of the photodiode structure 1 is a semiconductor chip but is not limited hereto. In one embodiment of the present invention, the chip 10 may include a first semiconductor layer 11 and a second semiconductor layer 12. In the following embodiment, the first semiconductor layer 11 is made of an N-type semiconductor, while the second semiconductor layer 12 is made of a P-type semiconductor. However, the type of semiconductor layers may be changed according to design requirements. After formation of the first semiconductor layer 11, a recess 11a may be formed on the exposed surface of the first semiconductor layer 11, and the second semiconductor layer 12 may be formed in the recess 11a. The first semiconductor layer 11 and the second semiconductor layer 12 cooperatively form a surface, which is defined as the top surface 13 of the chip 10 in the present invention.

The electrode group 20 is arranged on the top surface 13 of the chip 10. The electrode group 20 comprises a positive electrode 21 and a negative electrode 22. In the present invention, the positive electrode 21 is in contact with the second semiconductor layer 12 of the chip 10, while the negative electrode 22 is in contact with the first semiconductor layer 11 of the chip 10. However, the present invention is not limited hereto.

The electrode protection layer 30 is disposed on the top surface 13 of the chip 10 for protection of the electrode group 20. In the present invention, the electrode protection layer 30 has a thickness measured from the top surface 13 of the chip 10. The thickness of the electrode protection layer 30 is greater than the height of the electrode group 20 (i.e., the positive electrode 21 and the negative electrode 22) so that the electrode protection layer 30 covers the electrode group 20 while the electrode group 20 is not exposed from the electrode protection layer 30. In one embodiment of the present invention, the electrode protection layer 30 is made of an optical transparent glue or an optical transparent photoresist. For example, the optical transparent glue may include, for example, but not limited to, siloxanes, polysiloxanes (silicones), acrylics, or epoxy resins. The optical transparent photoresist may include, for example, but not limited to, siloxanes or acrylics. In one embodiment of the invention, the electrode protection layer 30 has a refractive index ranging from 1.45 to 1.6.

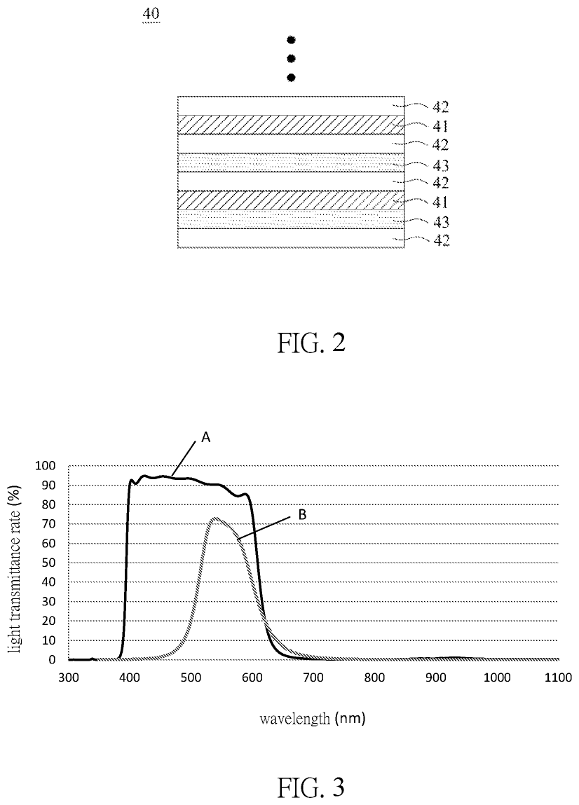

The metal alloy band-pass optical film 40 is disposed on the electrode protection layer 30. The metal alloy band-pass optical film 40 is insulated from the electrode group 20 by the electrode protection layer 30 so that the metal alloy band-pass optical film 40 and the electrode group 20 are not in direct contact with each other and thus are electrically insulated from each other. The metal alloy band-pass optical film 40 comprises a plurality of layered structures formed in a stacking manner (please refer to the embodiment in FIG. 2). The layered structures include at least two layers of metal alloy. In one embodiment of the present invention, the metal alloy layers are made of, for example, but not limited to, a silver platinum alloy. For example, a silver aluminum alloy or other alloy may be used. For the aforementioned silver platinum alloy, a ratio of silver to platinum is approximately 95:5, but this ratio can be adjusted according to different designs. Furthermore, the layered structures may further include at least one of a silicon dioxide layer, a titanium dioxide layer, a tantalum pentoxide layer and a niobium pentoxide layer.

The photodiode structure 1 of the present invention further includes a plurality of electric wires 50. Each electric wire 50 penetrates the metal alloy band-pass optical film 40 and the electrode protection layer 30 and is connected to the corresponding electrode of the electrode group 20. Each electric wire 50 has an outer insulating sheath so that unintended electrical connection between each electric wire 50 and the metal alloy band-pass optical film 40 is prevented.

Reference is made to FIG. 2 and FIG. 3. FIG. 2 is a schematic view of the metal alloy band-pass optical film of an embodiment of the photodiode structure according to the present invention. FIG. 3 is a comparison diagram of the test result of the photodiode structure of the embodiment according to the present invention and the conventional photodiode structure. As shown in FIG. 2, in the photodiode structure, the metal alloy band-pass optical film 40 is formed by for example, but not limited to, 21 layered structures stacked on the electrode protection layer. The metal alloy band-pass optical film 40 may be formed by less than 21 layered structures or by more than 21 layered structures. For example, in this embodiment, each of the third layer structure and the seventh layered structure is formed of a silver platinum alloy layer 41 (the number and position of the silver platinum alloy layers 41 can be adjusted according to different designs, not limited to the third and the seventh layers). The rest of layered structures are alternately formed of a silicon dioxide material layer 42 and a titanium dioxide material layer 43. The detailed composition and the thickness range of each layered structure are shown in Table 1. As compared to the metal band-pass optical film formed of more than 50 layered structures as used in the conventional photodiode structure, the photodiode structure 1 of the present invention effectively reduces the number and thickness of the layered structures by introduction of the metal alloy material layers. Thus, the overall process will be simplified, and the manufacturing cost will be reduced.

TABLE 1

| | Sequence number of the layered structure | | | | | | |
|---|---|---|---|---|---|---|---|
| | 1 | 2 | 3 | 4 | 5 | 6 | 7 |
| Materials | SiO₂ | TiO₂ | Ag—Pt | SiO₂ | TiO₂ | SiO₂ | Ag—Pt |
| Thickness | 48.251~89.609 | 15.127~28.093 | 10.934~20.306 | 55.545~103.155 | 7.224~13.416 | 10.225~19.045 | 15.246~28.314 |
| range(nm) | | | | | | | |
| | Sequence number of the layered structure | | | | | | |
| | 8 | 9 | 10 | 11 | 12 | 13 | 14 |
| Materials | SiO₂ | TiO₂ | SiO₂ | TiO₂ | SiO₂ | TiO₂ | SiO₂ |
| Thickness | 10.262~19.058 | 8.155~15.145 | 61.719~114.621 | 40.46~75.14 | 102.228~189.852 | 40.74~75.66 | 104.601~194.259 |
| range(nm) | | | | | | | |
| | Sequence number of the layered structure | | | | | | |
| | 15 | 16 | 17 | 18 | 19 | 20 | 21 |
| Materials | TiO₂ | SiO₂ | TiO₂ | SiO₂ | TiO₂ | SiO₂ | TiO₂ |
| Thickness | 41.384~76.856 | 36.82~68.38 | 3.304~6.136 | 59.353~110.227 | 34.846~64.714 | 25.417~47.203 | 9.051~16.809 |
| range(nm) | | | | | | | |

As shown in FIG. 3, Curve A represents the test results of the embodiment of the photodiode structure of the present invention, while Curve B represents the test results of the conventional photodiode structure. It can be seen that the conventional metal band-pass optical film has a transmission wavelength range of only about 500 nm to 620 nm. In contrast, due to formation of the aforementioned metal alloy band-pass optical film 40, the photodiode structure 1 of the present invention has a transmission wavelength range of about 400 nm to 620 nm. As compared to the conventional metal band-pass optical film, the photodiode structure 1 of the present invention has a better transmission wavelength range. For the light in the wavelength range between 530 nm to 550 nm, the conventional metal band-pass optical film has a light transmittance rate of about 70% or more. In contrast, for the light in a wavelength range between 400 nm to 600 nm, the metal alloy band-pass optical film of the photodiode structure 1 of the present invention has a light transmittance rate of about 80% or more, and even more than about 90%. For the light in the wavelength range between 300 nm to 399 nm, the metal alloy band-pass optical film of the photodiode structure 1 of the present invention has a light transmittance rate less than 1%. As compared to the conventional metal band-pass optical film, the photodiode structure 1 of the present invention has a better light transmittance rate for the light in a wider wavelength range.

As evident from the above embodiment, in the photodiode structure of the present invention, a metal alloy band-pass optical film with a silver platinum alloy material layer is used so that improvement of the tolerance to environmental testing and reduction of the occurrence of metal oxidation migration phenomenon are achieved by the properties of platinum metal. The number of layers and thickness of the metal alloy band-pass optical film can be effectively reduced. Therefore, production capacity can be enhanced, and the manufacturing costs can be reduced. Additionally, in the photodiode structure 1 of the present invention, the electrode group and electrode protection layer are directly formed on the chip so that there is no need to form additional oxide and/or nitride protection layers on the chip as in conventional photodiode structures. The electrode group and the chip are effectively protected, and the electrode group is prevented from being in contact with the metal alloy band-pass optical film.

The above embodiments are provided for illustrative purposes and are not intended to limit the embodiments or their applications or uses. Additionally, although at least one exemplary embodiment has been presented in the above embodiments, it should be understood that the present invention can have many variations. It should also be understood that the embodiments described herein are not intended to limit the scope, application, or configuration of the claimed subject matter in any way. On the contrary, the embodiments described above can provide a convenient guide for those skilled in the art to implement one or more embodiments. Furthermore, various changes can be made to the functionality and arrangement of the components without departing from the scope defined by the claims, and the claims encompass known equivalents and foreseeable equivalents at the time of filing of this patent application.

What is claimed is:

1. A photodiode structure, including:
a chip;
an electrode group, arranged on the chip, the electrode group including a positive electrode and a negative electrode;
an electrode protection layer, arranged on the chip and covering the electrode group; and
a metal alloy band-pass optical film, arranged on the electrode protection layer, the metal alloy band-pass optical film including a plurality of layered structures, wherein the plurality of layered structures includes at least two metal alloy material layers.

2. The photodiode structure of claim 1, wherein the electrode protection layer is made of an optical transparent glue or an optical transparent photoresist.

3. The photodiode structure of claim 2, wherein the optical transparent glue comprises siloxanes, polysiloxanes, acrylics, or epoxy resins.

4. The photodiode structure of claim 2, wherein the optical transparent photoresist comprises siloxanes or acrylics.

5. The photodiode structure of claim 1, wherein the electrode protection layer has a refractive index ranging between 1.45 and 1.6.

6. The photodiode structure of claim 1, wherein the electrode protection layer has a thickness measured from a top surface of the chip and greater than a height of the electrode group.

7. The photodiode structure of claim 1, wherein each of the metal alloy material layers is made of a silver platinum alloy material.

8. The photodiode structure of claim 7, wherein a ratio of silver to platinum in the silver-platinum alloy material is 95:5.

9. The photodiode structure of claim 1, wherein the plurality of layered structures further includes at least one of a silicon dioxide layer, a titanium dioxide layer, a tantalum pentoxide layer and a niobium pentoxide layer.

10. The photodiode structure of claim 1, wherein for a light in a wavelength range between 400 nm to 600 nm, the metal alloy band-pass optical film has a light transmittance of 80% or more.

11. The photodiode structure of claim 10, wherein for a light in a wavelength range between 300 nm to 399 nm, the metal alloy band-pass optical film has a light transmittance of 1% or less.

12. The photodiode structure of claim 1, further including a plurality of electric wires, and each of the electric wires penetrates the metal alloy band-pass optical film and the electrode protection layer and is connected to the electrode group.
